(19) United States
(12) Patent Application Publication
(10) Pub. No.: US 2008/0124930 A1
(43) Pub. Date: May 29, 2008

(54) METHODS OF RECYCLING A SUBSTRATE INCLUDING USING A CHEMICAL MECHANICAL POLISHING PROCESS

(75) Inventors: Jong Heun Lim, Seoul (KR); Chang-Ki Hong, Seongnam-si (KR); Bo-Un Yoon, Seoul (KR); Dae-Lok Bae, Seoul (KR); Seong-Kyu Yun, Seoul (KR); Suk-Hun Choi, Suwon-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/945,359

(22) Filed: Nov. 27, 2007

(30) Foreign Application Priority Data
Nov. 28, 2006 (KR) 10-2006-0117987

(51) Int. Cl. H01L 21/302

(52) U.S. Cl. 438/692; 257/E21.214

(57) ABSTRACT

In a method of recycling a substrate having an edge portion on which a stepped portion is formed, the substrate is chemically mechanically polished using a first slurry composition including fumed silica to remove the stepped portion. The substrate is then chemically mechanically polished using a second slurry composition including colloidal silica to improve the surface roughness of the substrate. The substrate having the edge region on which the stepped portion is formed may include a donor substrate used for manufacturing a silicon-on-insulator (SOI) substrate.

### CROSS-REFERENCE TO RELATED APPLICATION

This application claims priority to Korean Patent Application No. 10-2006-117987 filed on Nov. 28, 2006, the disclosure of which is incorporated herein by reference in its entirety.

### FIELD OF THE INVENTION

Embodiments of the present invention relate to methods of recycling a substrate. More particularly, the present invention relates to methods of recycling a substrate having a stepped portion on an edge region of the substrate that is used for a process for manufacturing a silicon-on-insulator (SOI) substrate.

### BACKGROUND OF THE INVENTION

Generally, as semiconductor devices have become highly integrated, leakage current in a junction region caused by a parasite capacitance may increase the power consumption of the semiconductor device. This may block semiconductor device fabrication requiring a rapid operation speed and a relatively low power. Particularly, as the channel length of a transistor, which may occupy a large area of the semiconductor device, has been reduced to no more than about 0.5 μm, the integration degree of semiconductor substrates has increased. Therefore, a junction capacitance and a leakage current in source/drain electrodes of a metal oxide semiconductor (MOS) transistor may be increased. As a result, to provide the semiconductor device with a rapid operational speed and a low power by reducing the parasite capacitance and the leakage current, a silicon-on-insulator (SOI) substrate has been used.

The SOI substrate may have a structure including a single crystalline semiconductor layer on an insulator. During manufacture of a semiconductor device, an isolation process may be readily carried out on the SOI substrate. Further, the SOI substrate may have improved electrical characteristics such as a low voltage of below about 1V of an electronic circuit element, a high speed, a low power, etc. The SOI substrate may be used for an ultra large-scale integrated (ULSI) circuit, a Gb-DRAM, a radiation-resistant high circuit, a micro electro mechanical system (MEMS), a solar cell, etc.

The SOI may be manufactured by a separation implanted oxygen (SIMOX) method or by an ion cutting method. According to the SIMOX method, oxygen atoms are implanted into a silicon substrate to form a substrate doped with the oxygen atoms. The substrate doped with the oxygen atoms is then annealed to form the SOI substrate. A trench is then formed at a surface portion of the SOI substrate. The trench is filled with an insulation layer to form a field region and an active region of the SOI substrate. When a fundamental electrode of the MOS transistor is formed on the SOI substrate, source/drain electrodes of the MOS transistor may make contact with an insulation layer under a silicon layer in the active region so that a junction capacitance and a leakage current may not exist. As a result, a semiconductor substrate for use in a semiconductor device operating with a lower power and rapid operational speed may be obtained. Further, devices may be electrically isolated from each other by the insulation layer.

In contrast, according to the ion cutting method, substrates having insulation layers are attached to each other. The attached substrates are then etched-back. Particularly, hydrogen ions are implanted into a donor substrate having a silicon oxide layer to form an ion implantation region in the donor substrate. The donor substrate is overlapped with a handling substrate to form a stacked structure. The stacked structure is combined at a high temperature. The donor substrate is then separated from the ion implantation region. The handling substrate is thermally treated and chemically mechanically polished to form the SOI substrate having a low surface roughness. The SOI substrate manufactured by the ion cutting method may have improved characteristics such as a uniform thickness, crystallization, etc., compared to that manufactured by the SIMOX method. Further, the ion cutting method may be compatible with a general semiconductor fabrication process.

In this instance, the used donor substrate may be recycled in the ion cutting method to decrease the expense of the donor substrate among the total expense of the semiconductor device. Conventional methods of recycling a donor substrate are discussed in Korean Patent Laid-Open Publication Nos. 2002-85361 and 2005-91071.

The process for recycling the donor substrate may be carried out for removing a stepped portion on an edge region of the separated donor substrate. More specifically, since the edge portion of the donor substrate may have a rounded shape, the rounded edge portion may not be attached to a handling substrate. Thus, the edge portion of the donor substrate may not be separated along a line substantially horizontal with a cut face of the separated donor substrate to form the stepped portion. Further, the process for recycling the donor substrate may be performed to remove a damaged layer, which may cause scratches at the cut face of the separated donor substrate caused by the ion implantation.

In a conventional method of recycling a donor substrate for manufacturing an SOI substrate, a donor substrate having a stepped portion is grinded. A surface of the grinded substrate is then etched using an etching solution. The surface of the etched substrate is thermally treated. Additionally, particles generated in the etching process may be removed by a cleaning process to recycle the donor substrate for manufacturing another SOI substrate. However, the conventional method may include the grinding process, the etching process, the thermal treatment process, etc., so that the donor substrate may be transferred to many units for performing the above-mentioned processes. As a result, the time for recycling the donor substrate may be lengthened and/or the process expensive. Therefore, a technique for recycling a donor substrate with a shortened processing time is desirable.

### SUMMARY OF THE INVENTION

Embodiments of the present invention provide methods of recycling a substrate that has a stepped portion of an edge region of the substrate used for manufacturing an SOI substrate.

According to methods of the present invention, methods of recycling a substrate in accordance with embodiments of the present invention include primarily chemically mechanically polishing the substrate having an edge portion on which a stepped portion is formed using a first slurry composition including fumed silica to remove the stepped portion. The substrate is then secondarily chemically mechanically polished using a second slurry composition including colloidal silica to improve a surface roughness of the substrate.

According to particular embodiments, the first slurry composition used in the primary chemical mechanical polishing (CMP) process may include about 5% to 20% by weight fumed silica abrasive particles, about 1% to 5% by weight potassium hydroxide as a pH control additive, about 0.01% to 1.0% by weight ammonium salt as a particle size control additive and water as the remaining component. Further, the second slurry composition used in the secondary CMP process may include about 0.01% to about 20% by weight colloidal silica abrasive particles, about 0.15% to about 1.0% by weight potassium hydroxide and potassium bicarbonate as a process aid additive, about 0.03% to about 0.50% by weight triethylenetetramin hexaacetic acid as chelate and water as the remaining component.

According to further embodiments, the primary CMP process may be carried out at a first polishing speed faster than a second polishing speed of the secondary CMP process. Particularly, the first polishing speed may be about 2 times to about 6 times the second polishing speed. Further, the primary and the secondary CMP processes may use a polishing pad including polyurethane.

According to still other embodiments, after performing the secondary CMP process, a cleaning process may be additionally carried out to remove foreign substances on the substrate. A cleaning solution including NH₄OH, H₂O₂ and/or H₂O may be used in the cleaning process. Further, after performing the cleaning process, an inspection process for inspecting the surface roughness of the substrate may be additionally carried out.

In further embodiments, the substrate having the edge region on which the stepped portion is formed may include a donor substrate used for manufacturing a silicon-on-insulator (SOI) substrate.

According to embodiments of the present invention, the substrate having the edge region on which the stepped portion is formed may be twice polished using the first slurry composition including the fumed silica and the second slurry composition including the colloidal silica to form the substrate having a flat surface. Thus, since the substrate may have improved surface flatness, the substrate may be recycled as a donor substrate for manufacturing an SOI substrate. Since the recycled donor substrate may be reused for a semiconductor fabrication process, the cost of manufacturing a semiconductor device may be curtailed. Further, the recycling methods of the present invention may be carried out using only a CMP apparatus so that the time for recycling the substrate may be remarkably shortened compared to that required in a conventional method where the substrate may be transferred to many units.

### BRIEF DESCRIPTION OF THE DRAWINGS

The above and other features and advantages of the invention will become readily apparent by reference to the following detailed description when considered in conjunction with the accompanying drawings wherein:

FIG. 1A presents a graph showing a polishing speed of a substrate using a first slurry composition including fumed silica in accordance with some embodiments of the present invention;

FIG. 1B presents a graph showing the polishing speed of a substrate using a second slurry composition including colloidal silica in accordance with some embodiments of the present invention;

FIG. 2 presents a flow chart illustrating methods of recycling a substrate in accordance with some embodiments of the present invention;

FIGS. 3 to 5 present cross-sectional views illustrating the method in FIG. 2; and

FIGS. 6 to 9 present cross-sectional views illustrating methods of manufacturing an SOI substrate using the recycling methods in accordance with some embodiments of the present invention.

### DETAILED DESCRIPTION OF EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. All publications, patent applications, patents, and other references mentioned herein are incorporated by reference in their entirety.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Moreover, it will be understood that steps comprising the methods provided herein can be performed independently or at least two steps can be combined. Additionally, steps comprising the methods provided herein, when performed independently or combined, can be performed at the same temperature and/or atmospheric pressure or at different temperatures and/or atmospheric pressures without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Methods of recycling a substrate in accordance with embodiments of the present invention include performing a chemical mechanical polishing (CMP) process on a silicon substrate having an edge region on which a stepped portion is formed. In this instance, the CMP process includes a primary CMP process using a first slurry composition including fumed silica, and a secondary CMP process using a second slurry composition including colloidal silica. According to particular embodiments, the stepped portion on the edge region of the substrate is removed by the primary CMP process. The surface roughness of the substrate can then be improved by the secondary CMP process. As a result, a substrate having a flat surface is completed by the primary and secondary CMP processes. According to embodiments of the invention, the first slurry composition used in the primary CMP process includes fumed silica abrasive particles, a pH control additive, a particle size control additive, and water as a dispersant. In this exemplary embodiment, the fumed silica used as the abrasive may be formed by oxidizing tetrachlorosilane (SiCl₄) at a temperature of about 1,100° C. under a hydrogen and oxygen atmosphere. Further, the fumed silica abrasive particles may be present in an amount of about 5% to about 20% by weight with respect to a total weight of the first slurry composition.

In further embodiments, the pH control additive may include potassium hydroxide present in an amount of about 0.1% to about 3.0% by weight with respect to the total weight of the first slurry composition. Further, the first slurry composition containing the pH control additive may have a basic pH of about 8 to about 12, and in some embodiments, about 11 to about 12.

According to some embodiments, the particle size control additive is added to the silica abrasive particles to control the particle size of the first slurry composition. In this exemplary embodiment, the particle size control additive may include ammonium salt such as alkyl trimethylammonium chloride, alkyl trimethylammonium bromide, etc. The alkyl may be a C₁ to C₃₀ alkyl. Examples of the ammonium may include tetramethylammonium chloride, tetramethylammonium bromide, cethyltrimethylammonium chloride, cethyltrimethylammonium bromide, octyl decyltrimethylammonium chloride, etc. The ammonium salt may be present in an amount from about 0.01% to about 1.0% by weight with respect to the total weight of the first slurry composition. The fumed silica including the ammonium salt may have an average particle distribution of about 5 nm to about 500 nm. Further, the first slurry composition including the fumed silica may have a high polish removal rate with respect to polysilicon and silicon oxide. In contrast, the first slurry composition including the fumed silica may not have an etching selectivity with respect to polysilicon and silicon oxide. In this instance, the primary CMP process may use a polishing pad including a hard material. For example, the polishing pad may include polyurethane.

According to embodiments of the present invention, the second slurry composition used in the secondary CMP process includes colloidal silica abrasive particles, a process aid additive, chelate and water as a dispersant. In this exemplary embodiment, the colloidal silica (SiO₂) used as the abrasive particles may be obtained by forming alkoxysilane by a sol-gel reaction between silicon and alcohol, by hydrating the alkoxysilane, and by filtering byproducts generated during the hydration process. The colloidal silica may be present in an amount from about 0.01% to about 20.0% by weight with respect to a total weight of the second slurry composition.

In further embodiments, the process aid additive may include potassium hydroxide and potassium bicarbonate. The potassium hydroxide and the potassium bicarbonate may be present in an amount from about 0.15% to about 1.0% by weight with respect to the total weight of the second slurry composition. In this exemplary embodiment, an amount of the potassium hydroxide may be two times that of the potassium bicarbonate. The process aid additive may satisfactorily suppress cohesion of the colloidal silica in the second slurry composition to reduce surface damage of an object that may be generated after polishing the object. In some embodiments, the chelate may suppress pollution caused by metal impurities in the second slurry composition. The chelate may effectively capture a metal such as iron, nickel, calcium, chrome, zinc, etc. Examples of the chelate may include, but are not limited to, carboxylic acid compounds such as ethylene diamine tetraacetic acid, diethylene triamine hentaacetic acid, triethylenetetramine hexaacetic acid, etc. The chelate may be present in an amount of about 0.03% to about 0.50% by weight with respect to the total weight of the second slurry composition. In this exemplary embodiment, the second slurry composition may have a basic pH of about 8 to about 12, and in some embodiments, about 11 to about 12. In this instance, the size and the amount of the abrasive particles used in the first and the second slurry compositions may affect the polishing efficiency of the polishing process. When the abrasive particles in the first and second slurry compositions have a larger size, high stresses may be applied to the stepped portion simultaneously with the polishing speed of the substrate being increased when the first and the second slurry compositions make contact with the substrate. The high stresses may cause grains to partially detach from the surface of the substrate. In contrast, when the abrasive particles in the first and the second slurry compositions are smaller, the grains may not be detached from the surface of the substrate when the first and the second slurry compositions make contact with the substrate. However, since the surface of the substrate may deteriorate after the polishing process, the size of the abrasive particles may have a more appropriate size. Further, the polishing speed of the substrate may be decreased. Therefore, to rapidly remove the stepped portion of the substrate, the fumed silica abrasive particles in the first slurry composition may have an average particle distribution of about 5 nm to about 500 nm. Further, to reduce the surface roughness of the substrate surface, the colloidal silica abrasive particles in the second slurry composition may have an average particle distribution of about 10 nm to about 60 nm smaller than that of the fumed silica abrasive particles. Thus, when the substrate is polished using the first and the second slurry compositions, the polished substrate may have a flat surface. Further, the secondary CMP process may employ a polishing pad having a hard material similar to the primary CMP process.

In this exemplary embodiment, the polishing pad may include polyurethane. Particularly, the second slurry composition including the colloidal silica may have an increased polishing speed with respect to polysilicon, and a slower polishing speed with respect to silicon oxide. That is, when the second slurry composition has a polishing selectivity with respect to the polysilicon, the second slurry composition may be properly applied to remove the polysilicon after performing the primary CMP process.

Hereinafter, the methods of the present invention are illustrated in detail with reference to following Examples.

### Example 1

A first slurry composition was synthesized. The first slurry composition included 12.5% by weight of fumed silica abrasive particle, 1.7% by weight of potassium hydroxide as a pH control additive, 0.06% by weight of tetramethylammonium chloride as a particle size control additive and water as the remaining component.

### Synthetic Example 2

A second slurry composition was synthesized. The second slurry composition included 17.0% by weight of colloidal silica abrasive particle, 0.5% by weight of potassium hydroxide and 0.25% by weight of potassium bicarbonate as a process aid, 0.15% by weight of triethylenetetramine hexaacetic acid as chelate and water as the remaining component.

### Evaluating Polishing Speeds of Slurries with Respect to Substrates in Accordance with Kinds of Abrasive Particles

To evaluate polishing speeds of slurries with respect to substrates in accordance with types of abrasive particles, the first slurry composition in Example 1 and the second slurry composition in Example 2 were prepared. The first slurry composition and the second slurry composition were provided to a CMP apparatus (product name “Reflextion” manufactured by AMAT company in U.S.). A primary CMP process was carried out two times on a first stepped portion on an edge region of a first substrate using the first slurry composition, which included 12.5% by weight of the fumed silica as the abrasive particle, for 30 seconds and 120 seconds to measure thickness variations of the polished first stepped portion. A secondary CMP process was carried out three times on a second stepped portion on an edge portion of a second substrate using the second slurry composition, which included 17% by weight of colloidal silica as the abrasive particle, for 60 seconds, 240 seconds and 420 seconds to measure thickness variations of the polished second stepped portion.

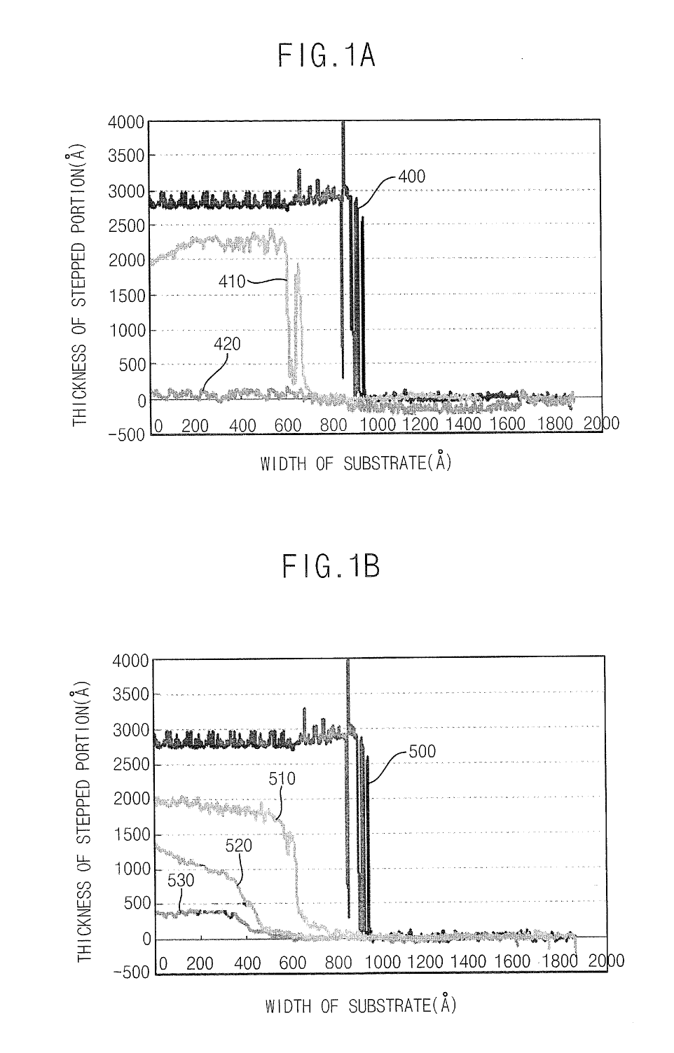

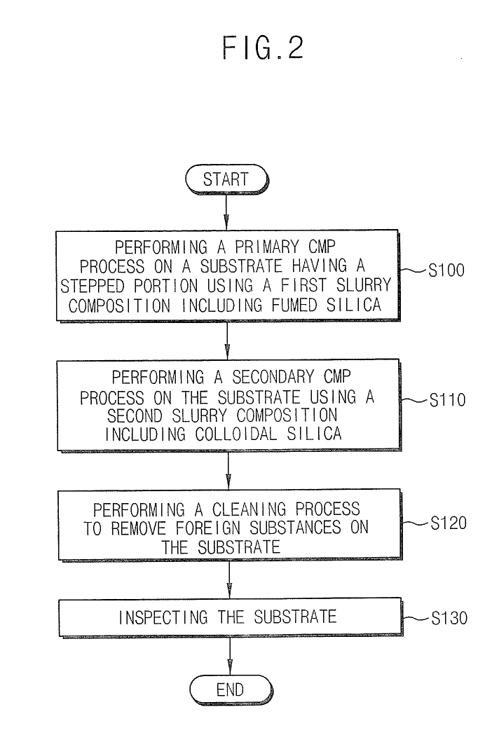

FIG. 1A presents a graph showing the polishing speed of the substrate using the first slurry composition including fumed silica in accordance with the present invention, and FIG. 1B presents a graph showing the polishing speed of the substrate using the second slurry composition including colloidal silica in accordance with embodiments of the present invention. In FIG. 1A, a line 400 represents an initial thickness of the first stepped portion, a line 410 indicates a thickness of the first stepped portion after performing the primary CMP process for 30 seconds, and a line 420 represents the thickness of the first stepped portion after performing the primary CMP process for 120 seconds. Further, in FIG. 1B, a line 500 represents an initial thickness of the second stepped portion, a line 510 indicates a thickness of the second stepped portion after performing the secondary CMP process for 60 seconds, a line 520 represents the thickness of the second stepped portion after performing the secondary CMP process for 240 seconds, and a line 530 indicates the thickness of the second stepped portion after performing the secondary CMP process for 420 seconds.

Referring to FIGS. 1A and 1B, when the thicknesses of the first stepped portion polished using the first slurry composition including the fumed silica are compared to the initial thickness of the first stepped portion, the thicknesses of the first stepped portion after 30 seconds and 120 seconds are reduced to 81.5% and 1.8% of the initial thickness of the first stepped portion, respectively. In contrast, when the thicknesses of the second stepped portion polished using the second slurry composition including the colloidal silica are compared to the initial thickness of the second stepped portion, the thicknesses of the second stepped portion after 60 seconds, 240 seconds and 420 seconds are reduced to 71.4%, 35.7% and 14.3% of the initial thickness of the second stepped portion, respectively. That is, the first stepped portion on the edge region of the first substrate having a thickness of about 2,500 Å to about 3,500 Å is polished at a relatively high polishing speed of about 20 Å/sec to about 30 Å/sec by the primary CMP process using the first slurry composition including the fumed silica. In contrast, the second stepped portion on the edge region of the second substrate having a thickness of about 2,500 Å to about 3,500 Å is polished at a relatively low polishing speed of about 5 Å/sec to about 9 Å/sec by the secondary CMP process using the second slurry composition including the colloidal silica.

Thus, the primary CMP process using the first slurry composition including the fumed silica has a polishing speed ratio of about 2:1 to about 6:1 with respect to that of the secondary CMP process using the second slurry composition including the colloidal silica. Further, in the primary CMP process using the first slurry composition including the fumed silica, it can be noted that the thickness of the substrate surface is not uniformly maintained after removing the first stepped portion. In contrast, in the secondary CMP process using the second slurry composition including the colloidal silica, it can be noted that the thickness of the substrate surface is uniformly maintained after removing the second stepped portion.

Therefore, to rapidly remove the stepped portion on the edge region of the substrate, the primary CMP process using the first slurry composition including the fumed silica may be beneficially employed, at least where the primary CMP process has a fast polishing speed. Further, to improve the flat appearance of the substrate surface, the secondary CMP process using the second slurry composition including the colloidal silica may be beneficially employed.

### Method of Recycling a Substrate

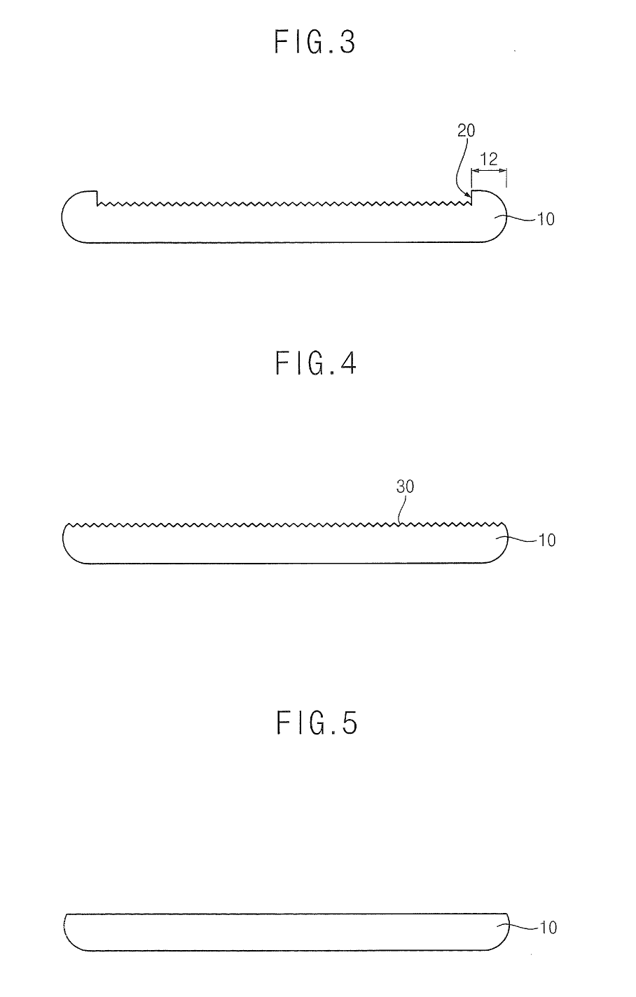

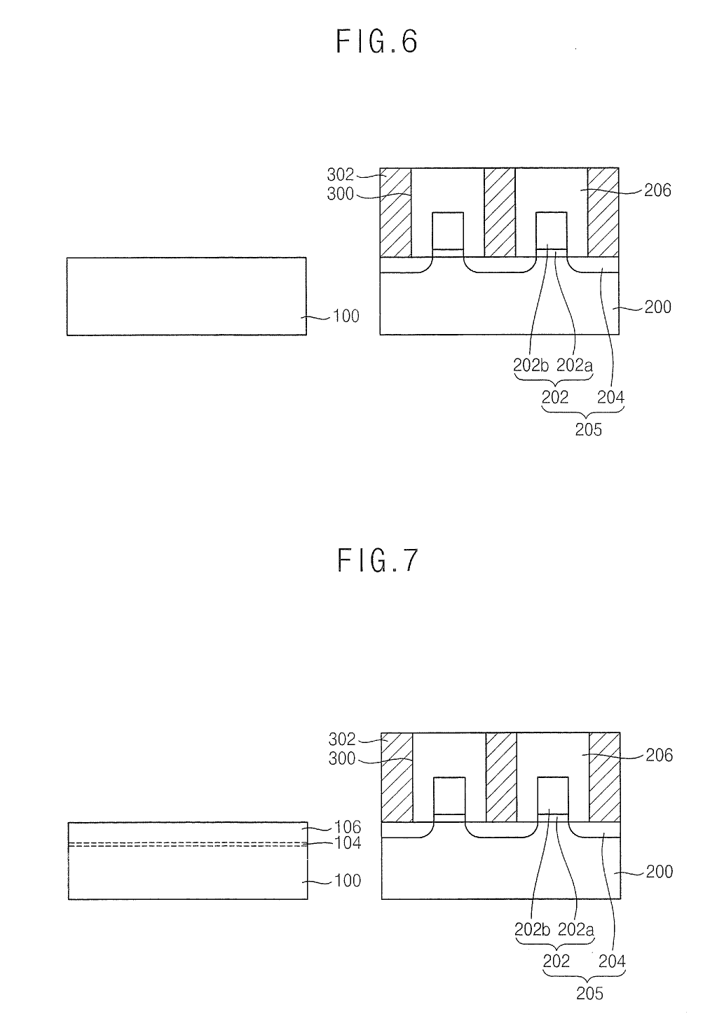

FIG. 2 presents a flow chart illustrating a method of recycling a substrate in accordance with some embodiments of the present invention, and FIGS. 3 to 5 present cross-sectional views illustrating the method in FIG. 2. Referring to FIGS. 2 and 3, in step S100, a primary CMP process is carried out on a stepped portion 20 on an edge region 12 of a silicon substrate 10 to remove the stepped portion 20. The stepped portion 20 may have an upper face higher than a central upper face of the substrate 20.

The primary CMP process may use a first slurry composition including fumed silica. In this exemplary embodiment, the first slurry composition may include about 5.0% to about 20.0% by weight of fumed silica abrasive particles, about 0.1% to about 3.0% by weight of potassium hydroxide as a pH control additive, about 0.01% to about 1.0% by weight of ammonium salt as a particle size control additive and water as the remaining component. The first slurry composition may be applied to a polishing pad. The polishing pad may include polyurethane. A surface of the substrate 10 having the edge region 12 on which the stepped portion 20 is formed may make contact with a surface of the polishing pad to remove the surface of the substrate 10. As a result, as shown in FIG. 4, the stepped portion 20 may be removed to expose a rough surface 30 of the substrate 10.

Further, the polishing pad and the substrate 10 having the stepped portion 20 may be rotated in opposite directions. The substrate 10 may then be pressurized. The pressurized substrate 10 may make contact with the polishing pad. Thus, the stepped portion 20 of the substrate 10 may be chemically polished by the first slurry composition including the fumed silica. Further, the stepped portion 20 of the substrate 10 may be mechanically polished by the rotation and the pressurization. The first slurry composition including the fumed silica has been previously illustrated.

Thus, any further illustrations with respect to the first slurry composition are omitted herein for brevity.

A removed thickness of the stepped portion 20 on the edge region 12 of the substrate 10 by the primary CMP process may be about 500 Å to about 10,000 Å. In this exemplary embodiment, the removed thickness of the stepped portion 20 may be about 3,000 Å. Further, the primary CMP process may be performed until the surface of the substrate 10 is uniform. The surface uniformity of the substrate 10 may be defined as a root mean square (RMS). Further, the surface uniformity of the substrate 10 may be determined based on the roughness measured using a nuclear microscope, an atomic force microscope, etc. Particularly, the primary CMP process may be carried out until the RMS of the substrate 10 is about 4 Å.

In this exemplary embodiment, the first slurry composition may have a pH of about 8 to about 12. Further, the first slurry composition may have a polishing speed of about 20 Å/sec to about 30 Å/sec with respect to the silicon substrate 10. Since the first slurry composition includes the pH control additive and the particle size control additive, the polishing speed may be readily controlled.

Referring to FIGS. 2 and 5, in step S110, a secondary CMP process is then carried out on the primarily polished surface of the substrate 10 to remove and planarize the rough surface 30 of the substrate 10. In this exemplary embodiment, the secondary CMP process may use a second slurry composition including colloidal silica. The second slurry composition may include about 0.01% to about 20.0% by weight of colloidal silica abrasive particles, about 0.15% to about 1.0% by weight of potassium hydroxide and potassium bicarbonate as a process aid additive, about 0.03% to about 0.50% by weight of triethylenetetramine hexaacetic acid as chelate, and water as the remaining component. Further, the secondary CMP process may use a polishing pad including polyurethane.

The polishing pad and the substrate 10 may be rotated in opposite directions. The substrate 10 may then be pressurized. The pressurized substrate 10 may make contact with the polishing pad. Thus, the stepped portion 20 of the substrate 10 may be chemically polished by the second slurry composition including the colloidal silica. Further, the stepped portion 20 of the substrate 10 may be mechanically polished by the rotation and the pressurization. The second slurry composition including the colloidal silica has been previously illustrated. Thus, any further illustrations with respect to the second slurry composition are omitted herein for brevity.

In this exemplary embodiment, the secondary CMP process may be carried out until the RMS of the substrate 10 is no more than about 2 Å. In some embodiments, the secondary CMP process may be carried out until the RMS of the substrate 10 is no more than about 1 Å. A polished depth of the substrate 10 may be selectively adjusted in accordance with kinds of impurities in the surface of the substrate 10. Further, the second slurry composition may have a pH of about 8 to about 12. Further, the second slurry composition may have a polishing speed of about 5 Å/sec to about 9 Å/sec with respect to the silicon substrate 10 slower than that of the first slurry composition. Thus, a polishing speed ratio of the primary CMP process with respect to the secondary CMP process may be about 2:1 to about 6:1. Further, the second slurry composition includes the process aid additive and the chelate; the colloidal silica may not be cohered. Further, pollution of the substrate 10 caused by metal impurities may be prevented.

In step S120, after completing the secondary CMP process, a cleaning process is then performed on the substrate 10 to remove particles remaining on the substrate 10. In this exemplary embodiment, the cleaning process may include a physical cleaning process using brushes. In the physical cleaning process, the different brushes may scrub the front and rear faces of the substrate 10 with a cleaning solution being provided to the substrate 10. Further, the cleaning process may use a standard clean-1 (SC-1) solution including NH₄OH, H₂O₂ or H₂O.

In step 3130, an inspection process is then carried out on the cleaned substrate 10 to measure a thickness of the substrate 10. In this exemplary embodiment, the deformation degree of the substrate 10 such as thickness uniformity of the substrate 10, bend of the substrate 10, an average thickness of the substrate 10, etc., may be measured together with measuring the thickness of the substrate 10. When the thickness and the deformation degree of the substrate 10 are within allowable ranges, pollution degree of the substrate 10 such as numbers of particles, pollution degree of metal atoms, etc., may be further inspected. Thus, when the measured pollution degree of the substrate 10 may be within an allowable range, the substrate 10 may be reused as a donor substrate for manufacturing an SOI substrate.

A method of manufacturing the SOI substrate using the recycled donor substrate is illustrated in detail.

### Method of Manufacturing an SOI Substrate

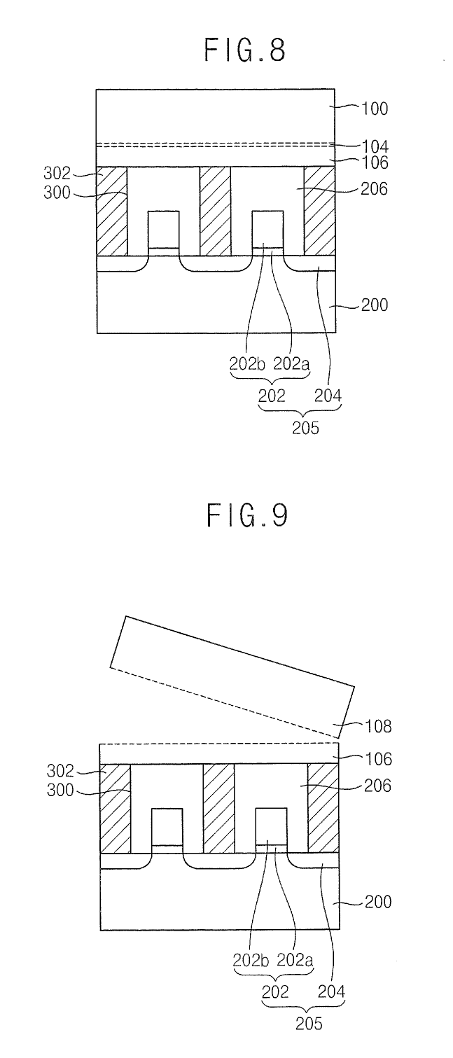

FIGS. 6 to 9 present cross-sectional views illustrating methods of manufacturing an SOI substrate using the recycling method according to embodiments of the present invention.

Referring to FIG. 6, a handling substrate 200 is arranged over a donor substrate 100 having a recycled surface layer 106 (see FIG. 4). In this exemplary embodiment, the handling substrate 200 may include a semiconductor structure 205 and an oxide layer pattern 206. Further, examples of the donor substrate 100 and the handling substrate 200 may include, but are not limited to, a silicon substrate, a silicon-on-insulator substrate, a germanium substrate, a germanium-on-insulator substrate, a silicon-germanium substrate, etc. Furthermore, since the surface layer 106 of the donor substrate 100 may be used as a channel layer of a stack type semiconductor device, the donor substrate 100 may include a single crystalline layer obtained by a selective epitaxial growth (SEG) process.

A trench isolation layer (not shown) as an isolation layer is then formed in the handling substrate 200 to define an active region and a field region of the handling substrate 200. In this instance, the trench isolation layer may improve an integration degree of a semiconductor device.

The semiconductor structure 205 is then formed on the active region of the handling substrate 200. In this exemplary embodiment, the semiconductor structure 205 may include a transistor including a gate pattern 202 and source/drain regions 204. Further, the gate pattern 202 may include a gate insulation layer 202a and a gate conductive layer 202b.

The semiconductor structure 205 such as the transistor including the gate pattern 202 and the source/drain regions 204 may be formed by the following processes. An insulation layer (not shown) and a conductive layer (not shown) are formed on the handling substrate 200. The insulation layer and the conductive layer are patterned to form the gate pattern 202. Particularly, a photoresist pattern is formed on the conductive layer to partially expose the conductive layer. The conductive layer and the insulation layer are etched using the photoresist pattern as an etching mask to form the gate pattern 202 including the gate insulation layer 202a and the gate conductive layer 202b on the handling substrate 200. The photoresist pattern is then removed by an ashing process and/or a stripping process. Impurities are implanted into the handling substrate 200 using the gate pattern 202 as an ion implantation mask to form the source/drain regions 204 at a surface portion of the handling substrate 200 adjacent to the gate pattern 202. The impurities may include boron (B), phosphorous (P), arsenic (As), etc. When the stack type semiconductor device includes a double stack type SRAM device, an NMOS transistor may be formed on a lower semiconductor substrate. Thus, the impurities may include phosphorous or arsenic.

Alternatively, the source/drain regions 204 may have a lightly doped drain (LDD) structure. The source/drain regions 204 having the LDD structure may be obtained by forming a spacer (not shown) on a sidewall of the gate pattern 202, and implanting impurities into the source/drain regions 204 to form the LDD structure.

In this exemplary embodiment, the semiconductor structure 205 includes the transistor having the gate pattern 202 and the source/drain regions 204. Alternatively, the semiconductor structure 205 may include a logic device, wiring, etc., in accordance with a circuit design. An oxide layer is then formed on the handling substrate 200 having the semiconductor structure 205 that includes the gate pattern 202 and the source/drain regions 204. Examples of the oxide layer may include, but are not limited to, a borophosphor silicate glass (BPSG) layer, a phosphor silicate glass (PSG) layer, an undoped silicate glass (USG) layer, a spin on glass (SOG) layer, etc. In this exemplary embodiment, the oxide layer is patterned to form an oxide layer pattern 206 having openings 300 that expose the surface of the donor substrate 200. The oxide layer pattern 206 may correspond to a buried oxide layer of the SOI substrate.

An SEG process is then carried out on the exposed surfaces of the handling substrate 200 through the openings 300 to form contacts 302 in the openings 300. The contacts 302 may have a crystalline structure substantially the same as that of the handling substrate 200. Thus, when the handling substrate 200 includes a single crystalline silicon substrate, the contact 302 may include a single crystalline silicon contact formed by an SEG process.

Referring to FIG. 7, hydrogen ions are implanted into the donor substrate 100 to form an ion implantation region 104. The ion implantation region 104 may define the surface layer 106 of the donor substrate 100 making contact with the handling substrate 200. In this exemplary embodiment, the dose of the hydrogen ions for forming the ion implantation region 104 may be about 1×10¹⁶/cm² to about 1×10¹⁷/cm₂. Further, the ion implantation region 104 may have a relatively thin thickness. When the donor substrate 100 is separated from the handling substrate 200 by a following process, the ion implantation region 104 may be cut to form a cut face doped with the hydrogen ions.

Referring to FIG. 8, the donor substrate 100 is attached to the handling substrate 200 to place the surface layer 106 on the semiconductor structure 205 and the oxide layer pattern 206.

Referring to FIG. 9, the donor substrate 100 and the handling substrate 200 attached to each other are then thermally treated to cut the donor substrate 100 along the ion implantation region 104. As a result, the surface layer 106 is still attached to the handling substrate 200. In this exemplary embodiment, the thermal treatment may be carried out at a temperature of about 300° C. to about 700° C. When the thermal treatment is carried out at a temperature of below about 300° C., the ion implantation region 104 may not be easily cut. In contrast, when the thermal treatment is carried out at a temperature of above about 700° C., thermal budge may be applied to the semiconductor structure 205 and the oxide layer pattern 206. As a result, the surface layer 16 is formed on the oxide layer pattern 206 of the handling substrate 200. After the donor substrate 100 is at least partially separated from the handling substrate 200 by the thermal treatment, a bonding strength of an interface between the surface layer 106 and the handling substrate 200 may be increased. Further, damage caused by the hydrogen ions in the donor substrate 100 and the ion implantation process may be removed. The surface layer 106 on the handling substrate 200 is then planarized to improve surface roughness of the cut face of the handling substrate 200. The separated donor substrate 100 is recycled. The recycled donor substrate 100 is then attached to a new handling substrate to complete an SOI substrate.

According to embodiments of the present invention, the substrate having the edge region on which the stepped portion is formed may be twice polished using the first slurry including the fumed silica and the second slurry including the colloidal silica to form the substrate having a flat surface. Thus, since the substrate may have an improved flat surface, the substrate may be recycled as a donor substrate for manufacturing an SOI substrate. Further, the recycling methods of the present invention may be carried out using a CMP apparatus so that the time for recycling the substrate may be remarkably shortened compared to that required in a conventional method where the substrate may be transferred to many units.

Having described various embodiments of the present invention, it is noted that modifications and variations can be made by persons skilled in the art in light of the above teachings. It is therefore to be understood that changes may be made in the particular embodiments of the present invention disclosed which are within the scope and the spirit of the invention outlined by the appended claims.

What is claimed is:

1. A method of recycling a substrate, comprising:
chemically mechanically polishing the substrate using a first slurry composition wherein the substrate comprises an edge portion on which a stepped portion is formed and the first slurry composition comprises fumed silica to remove the stepped portion of the substrate; and
chemically mechanically polishing the substrate using a second slurry composition comprising colloidal silica to improve a surface roughness of the substrate.

2. The method of claim 1, wherein the first slurry composition comprises:
about 5% to 20% by weight fumed silica abrasive particles;
about 1% to 5% by weight potassium hydroxide;
about 0.01% to 1.0% by weight ammonium salt; and water.

3. The method of claim 1, wherein the second slurry composition comprises:
about 0.01% to about 20% by weight colloidal silica abrasive particles;
about 0.15% to about 1.0% by weight potassium hydroxide and potassium bicarbonate;
about 0.03% to about 0.50% by weight triethylenetetramin hexaacetic acid; and
water.

4. The method of claim 1, wherein the first slurry composition has a basic pH in a range of about 8 to about 12.

5. The method of claim 1, wherein the second slurry composition has a basic pH in a range of about 8 to 12.

6. The method of claim 1, wherein the fumed silica has an average particle distribution in a range of about 5 nm to about 500 nm, and the colloidal silica has an average particle distribution in a range of about 10 nm to about 60 nm.

7. The method of claim 1, wherein the chemical mechanical polishing (CMP) process using the first slurry composition is carried out at a first polishing speed faster than a second polishing speed of the CMP process using the second slurry composition.

8. The method of claim 7, wherein the first polishing speed is about 2 times to about 6 times the second polishing speed.

9. The method of claim 1, wherein the CMP processes use a polishing pad comprising polyurethane.

10. The method of claim 1, wherein the CMP process using the second slurry composition is carried out until a root mean square of the substrate is no greater than about 2 Å.

11. The method of claim 1, wherein the stepped portion on the edge region of the substrate comprises an upper face higher than a central upper face of the substrate.

12. The method of claim 1, wherein the stepped portion on the edge region of the substrate is removed to a thickness of about 500 Å to about 10,000 Å.

13. The method of claim 1, further comprising performing a cleaning process to remove foreign substances on the substrate subsequent to performing the CMP process using the second slurry composition.

14. The method of claim 13, further comprising performing an inspection process for inspecting a surface roughness of the substrate subsequent to performing the CMP process using the second slurry composition.

15. The method of claim 13, wherein the cleaning process comprises using a cleaning solution including NH₄OH, H₂O₂ or H₂O.

16. The method of claim 1, wherein the substrate having the edge region on which the stepped portion is formed comprises a donor substrate configured for use in manufacturing a silicon-on-insulator (SOI) substrate.

17. The method of claim 1, wherein the CMP process using the second slurry composition is performed subsequent to performing the CMP process using the first slurry composition.
